(19) United States
(12) Patent Application Publication
(10) Pub. No.: US 2026/0223413 A1
(43) Pub. Date: Jul. 30, 2026

(54) Transistor and Display Device Including the Same

(71) Applicant: LG Display Co., Ltd., Seoul (KR)

(72) Inventors: Kyung Chul Ok, Paju-si (KR); Tae Hyoung Moon, Paju-si (KR); Ji Yong Noh, Paju-si (KR)

(21) Appl. No.: 19/409,159

(22) Filed: Dec. 4, 2025

(30) Foreign Application Priority Data
Jan. 24, 2025 (KR) 10-2025-0011978

(51) Int. Cl. H10D 30/67; H10D 86/40; H10D 86/60

(52) U.S. Cl. CPC H10D 30/6757; H10D 30/6723; H10D 30/6755; H10D 86/423; H10D 86/60

(57) ABSTRACT

Disclosed is a transistor including a gate electrode, an active layer comprising a channel area overlapping the gate electrode, and having bottom concave and convex portions and top concave and convex portions provided along a length direction of the channel area; and a first source drain electrode and a second source drain electrode connected to both sides of the active layer, the first source drain electrode and the second source drain electrode being spaced apart from the channel area of the active layer.

### CROSS-REFERENCE TO RELATED APPLICATIONS

This application claims the benefit of Republic of Korea Patent Application No. 10-2025-0011978, filed on January 24, 2025, which is hereby incorporated by reference as if fully set forth herein.

### BACKGROUND OF THE DISCLOSURE

### Field of the Disclosure

The present disclosure relates to a transistor, and more particularly to a transistor capable of improving reliability and a display device including the same.

### Discussion of the Related Art

Display devices for displaying images on TVs, monitors, smartphones, tablet computers, and laptop computers, etc. are used in various ways and forms.

A display device includes a plurality of pixels for implementing an image, and is provided with a transistor for controlling the operation of each pixel.

The display device includes a plurality of pixels, and is provided with a plurality of driving and switching elements for driving and controlling the pixels. The driving and switching elements may be constituted by transistors, and the transistors are widely used not only in pixels but also in integrated circuits.

In recent years, various research and development efforts have been made to improve the performance and reliability of transistors.

### SUMARY OF THE DISCLOSURE

Embodiments of the present disclosure provide a transistor configured such that a concave and convex structure is applied to an upper surface and a lower surface of an active layer, whereby it is possible to secure the channel length within a limited area of a substrate. Particularly, in a switching transistor used as a short channel, a sufficient channel length may be secured even when the area is limited, whereby it is possible to implement a stable transistor with a small dispersion range.

Embodiments of the present disclosure provide a transistor including a first transistor having concave and convex portions provided along a length direction of a channel of an active layer and a second transistor having concave and convex portions provided along a width direction of the channel, whereby it is possible to implement a transistor for different purposes such as channel length securing and on-current securing.

Embodiments of the present disclosure provide a transistor configured such that concave and convex portions may be provided along different directions depending on the characteristics of a transistor provided in a subpixel, whereby it is possible to define the channel characteristics for various purposes such as high-speed operation or gradation expression.

Embodiments of the present disclosure provide a transistor configured such that the effective channel length change of a transistor including an oxide semiconductor is controlled, whereby it is possible to improve reliability of the transistor.

Embodiments of the present disclosure provide a display device configured such that sensitivity to a channel width change is reduced, thereby increasing design freedom, and a small high-output transistor is disposed in a non-active area, thereby realizing a narrow bezel.

Embodiments of the present disclosure provide a display device configured such that the defect rate of the display device is reduced to reduce the amount of materials used in the process of manufacturing the display device, such as gas and an etching solution, whereby it is possible to reduce greenhouse gases generated by the manufacturing process.

A transistor according to an embodiment of the present disclosure includes a gate electrode, an active layer comprising a channel area overlapping the gate electrode, and having bottom concave and convex portions and top concave and convex portions provided along a length direction of the channel area; and a first source drain electrode and a second source drain electrode connected to both sides of the active layer, the first source drain electrode and the second source drain electrode spaced apart from the channel area of the active layer.

A display device according to an embodiment of the present disclosure comprise a first transistor comprising a first gate electrode and a first active layer overlapping the first gate electrode, having a first channel area, and having bottom concave and convex portions and top concave and convex portions along a length direction of the first channel area and a second transistor comprising a second gate electrode and a second active layer overlapping the second gate electrode, having a second channel area, and having bottom concave and convex portions and top concave and convex portions along a width direction of the second channel area.

A display device according to another embodiment of the present disclosure comprise a first transistor comprising a first gate electrode and a first active layer overlapping the first gate electrode, having a first channel area, and having bottom concave and convex portions and top concave and convex portions along a length direction of the first channel area and a second transistor comprising a second gate electrode and a second active layer overlapping the second gate electrode, having a second channel area, and having a flat lower surface and a flat upper surface along a length direction of the second channel area.

Each of the first active layer and the second active layer may include an oxide semiconductor.

The first transistor or the second transistor may be electrically connected to a light emitting device via a source drain electrode.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a schematic plan view showing a display device according to an embodiment of the present disclosure;

FIG. 2 is a circuit diagram showing a subpixel according to an embodiment of the present disclosure;

FIG. 3 is a plan view showing a transistor according to a first embodiment of the present disclosure;

FIG. 4 is a sectional view taken along line I-I’ of FIG. 3;

FIG. 5 is a plan view showing a transistor according to a second embodiment of the present disclosure;

FIG. 6 is a sectional view taken along line II-II’ of FIG. 5;

FIG. 7 is a sectional view taken along line III-III’ of FIG. 5;

FIG. 8 is a sectional view showing various transistors according to an embodiment of the present disclosure; and

FIG. 9 is a sectional view showing a display device according to an embodiment of the present disclosure.

### DETAILED DESCRIPTION OF THE DISCLOSURE

Advantages and features of the disclosure, and implementation methods thereof, will be clarified through the following embodiments described with reference to the accompanying drawings. However, the disclosure may be embodied in different forms and should not be construed as limited to the embodiments set forth herein. Rather, these embodiments are provided so that the disclosure will be thorough and complete, and will fully convey the scope of the disclosure to those skilled in the art. Further, the disclosure is defined only by the categories of the claims.

The same reference numerals designate the same constituent elements. Thicknesses, ratios, and dimensions of constituent elements may be exaggeratedly expressed in the drawings, for effective description of the technical content. In addition, the dimensions and scales of constituent elements shown in the drawings are different from actual dimensions and scales, for convenience of description and, as such, the dimension scales of constituent elements are not limited to those shown in the drawings.

It will be understood that, when one constituent element (or an area, a layer, a portion, or the like) is referred to as being “disposed on”, “connected to” or “coupled to” another constituent element, the one constituent element may be directly connected/coupled to the other constituent element, or a third constituent element may be disposed between the two constituent elements.

The term “and/or” is used to include one or more combinations of associated configurations.

It will be understood that, although the terms “first”, “second”, etc. may be used herein to describe various elements, these elements should not be limited by these terms. These terms are only used to distinguish one element from another. For example, a first element referred to in the following description may represent a second element, without departing from the scope of the disclosure. Similarly, the second element may represent the first element. Unless clearly used otherwise, singular expressions include a plural meaning.

Terms such as "below," "lower," "above," and "upper" are used to describe the relationships between the components shown in the drawings. These terms are relative concepts and are explained based on the orientations indicated in the drawings. For instance, unless "directly" or "immediately" is used, one or more other components may be disposed between two parts. Spatially relative terms such as "below", “beneath”, "lower," "above," and "upper" may be employed to easily describe the correlation between one device or component and other devices or components, as represented in the drawings. These spatially relative terms should be understood as encompassing different orientations of the devices when used or during operation, in addition to the directions shown in the drawings. For example, if the device in one of the drawings is turned over, elements described as "below" or "beneath" other elements would then be oriented "above" the other elements. Therefore, the exemplary term "below" may encompass both downward and upward directions.

In this specification, it is to be understood that a term, such as “include” or “have”, is intended to designate that a characteristic, a number, a step, an operation, an element, a part or a combination of them described in the specification is present, and does not preclude the presence or addition possibility of one or more other characteristics, numbers, steps, operations, elements, parts, or combinations thereof.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, a detailed description will be given of a display device according to embodiments of the present disclosure in conjunction with the attached drawings.

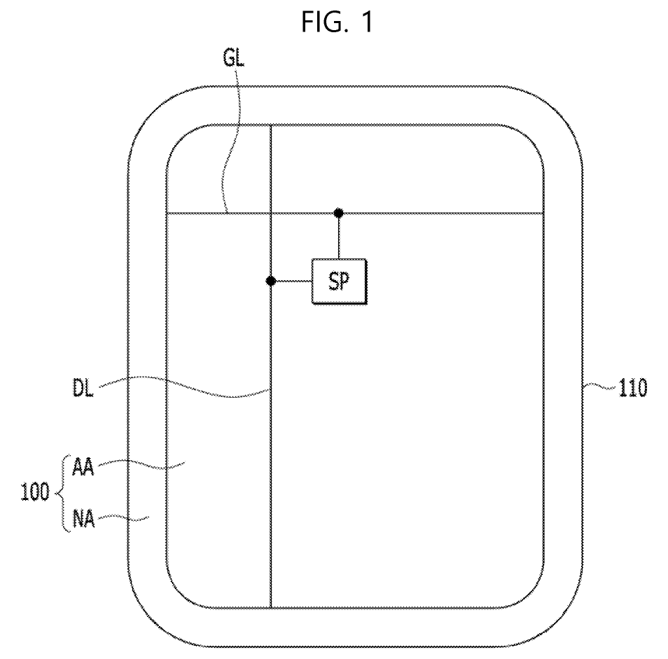

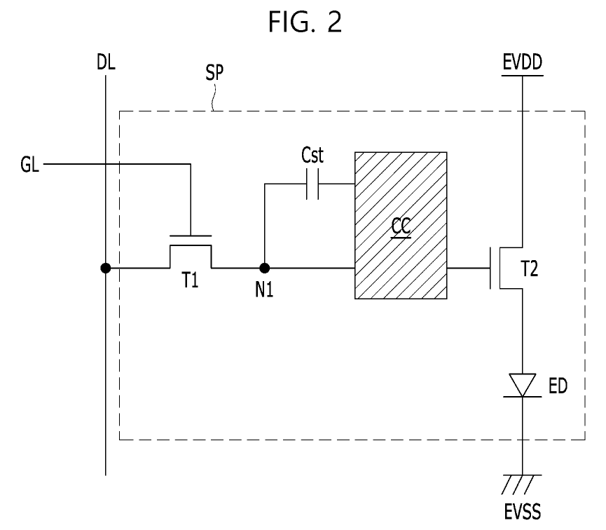

FIG. 1 is a schematic plan view showing a display device according to an embodiment of the present disclosure, and FIG. 2 is a circuit diagram showing a subpixel according to an embodiment of the present disclosure.

Referring to FIGS. 1 and 2, the display device 1000 according to the embodiment of the present disclosure may include a display panel 110 and a case (not shown) for receiving a side surface of the display panel 110 and a lower portion of the display panel 110. A non-active area NA of the display panel 110 may be covered by the case or by a separate printed film. A printed circuit film and/or a battery may be provided between the lower portion of the display panel 110 and the case.

The display panel 110 may include a substrate 100 including an active area AA and a non-active area NA surrounding the active area AA and a driving unit connected to the substrate 100. The driving unit may be integrated into the substrate 100 together with an array provided in the active area AA, may be connected to the substrate 100 via a film or connector in a COG (chip on glass) manner, or may be connected to a printed circuit board on the substrate 100 via a film or connector in a COF (chip on film) manner. Alternatively, the driving unit may include a configuration integrated into the substrate 100 and an external configuration of COG or COF. The display panel 110 may include a substrate 100 including an active area AA and a non-active area NA surrounding the active area AA, and a driving unit connected to the substrate 100.

The active area AA is an area for displaying an image. A plurality of subpixels SP may be disposed in the active area AA of the display panel 110, and an image may be displayed using the plurality of subpixels SP. The area outside the active area AA may be the non-active area NA.

The non-active area NA may be an edge area surrounding the active area AA that displays the image. At least one driving unit for driving the plurality of subpixels SP may be disposed in the non-active area NA. The driving unit may include a gate-in-panel GIP. The gate-in-panel GIP is connected to a plurality of gate lines GL of the active area AA and may sequentially supply gate voltage signals to the plurality of gate lines GL.

Various additional elements for driving the subpixels SP in the active area AA may be further disposed in the non-active area NA.

At least one of the plurality of subpixels SP may include, for example, a first transistor T1, a second transistor T2, a storage capacitor Cst, a compensation circuit CC, and a light emitting device ED, as shown in FIG. 2.

In an example, the first transistor T1 may be a switching transistor, and the second transistor T2 may be a driving transistor.

A first electrode (e.g., a drain electrode) of the first transistor T1 is electrically connected to the data line DL, and a second electrode (e.g., a source electrode) of the first transistor T1 is electrically connected to a first node N1. A gate electrode of the first transistor T1 is electrically connected to the gate line GL. The first transistor T1 transmits a data signal supplied through the data line DL to the first node N1 in response to a scan signal supplied through the gate line GL.

The storage capacitor Cst is electrically connected to the first node N1 and stores voltage applied to the first node N1.

A first electrode (e.g., a drain electrode) of the second transistor T2 receives a high voltage driving voltage EVDD, and a second electrode (e.g., a source electrode) is of the second transistor T2 electrically connected to a first electrode (e.g., an anode) of the light emitting device ED. The second transistor T2 may control the amount of driving current flowing in the light emitting device ED in response to the voltage applied to the gate electrode.

A semiconductor layer of the first transistor T1 and/or the second transistor T2 includes silicon, such as amorphous silicon (a-Si), polycrystalline silicon (poly-Si), or low-temperature polycrystalline silicon (low-poly-Si), or may include an oxide such as IGZO (indium-gallium-zinc-oxide), but the present disclosure is not limited thereto. At least one of the first and second transistors T1 and T2 includes an oxide semiconductor layer, which may be formed at a lower temperature than other materials, maintain amorphous characteristics, and have high mobility.

The light emitting device ED outputs light corresponding to the driving current. The light emitting device ED may output light corresponding to any one of red, green, blue, and white.

The light emitting device ED may include an anode (a first electrode), an intermediate layer disposed on the anode, and a cathode that supplies a common voltage. The intermediate layer includes at least one light emitting layer and may be implemented to emit light of the same color per pixel, such as white light, or to emit light of different colors per subpixel SP, such as red, green, or blue light. The intermediate layer may include various types of common layers and functional layers to efficiently supply holes and electrons to the light emitting layer.

The light emitting device ED may be a top emission diode or a bottom emission diode.

The compensation circuit CC may be provided in the subpixel SP in order to compensate for a threshold voltage of the second transistor T2. The compensation circuit CC may include one or more transistors. The compensation circuit CC may include one or more transistors and capacitors, and may be variously configured depending on a compensation method. The subpixel SP including the compensation circuit CC may include various circuit structures with different numbers of transistors and/or capacitors, such as 3T1C, 4T2C, 5T2C, 6T1C, 6T2C, 7T1C, and 7T2C.

Among the transistors provided in the subpixel, the switching transistor may require high-speed operation for fast switching.

In addition, the transistors are disposed in the subpixel with a limited area in the display device, and therefore each component must be disposed within the limited area.

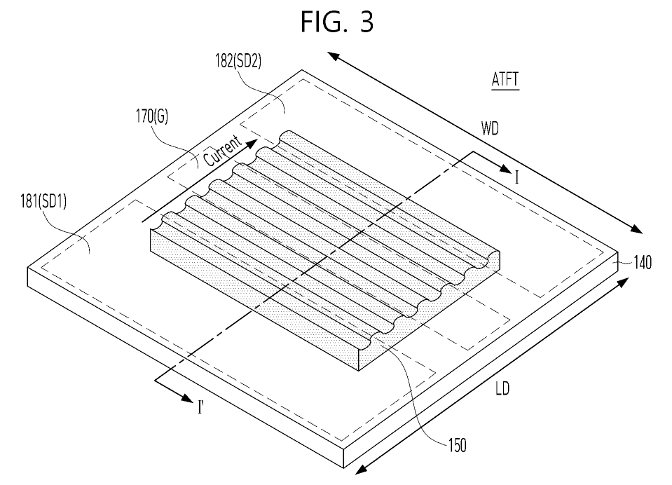

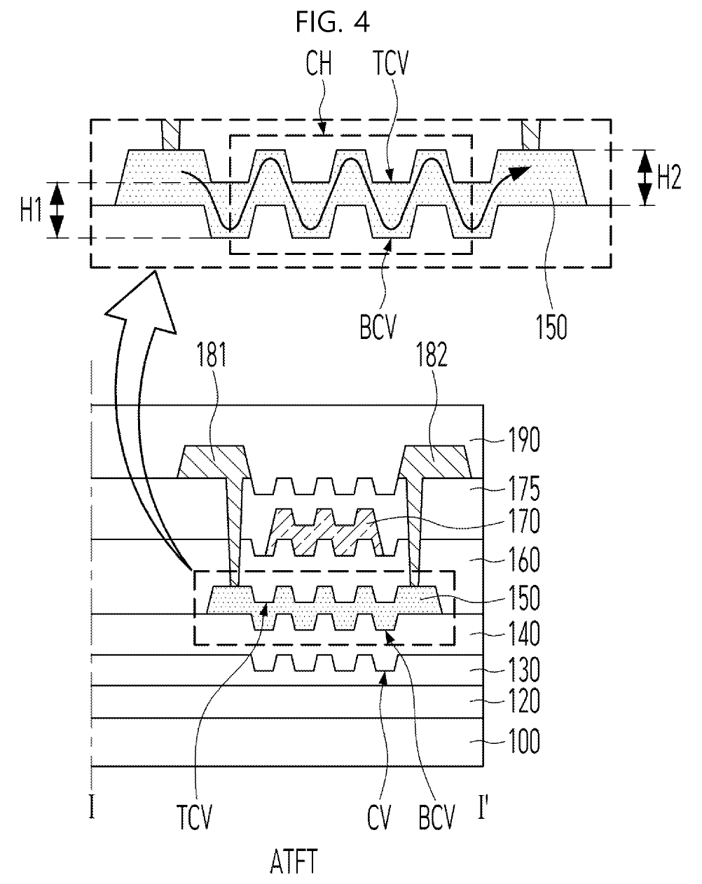

FIG. 3 is a plan view showing a transistor according to a first embodiment of the present disclosure, and FIG. 4 is a sectional view taken along line I-I’ of FIG. 3.

As shown in FIGS. 3 and 4, the transistor ATFT according to the first embodiment of the present disclosure may include a first gate electrode 170, a first active layer 150 having a channel area CH overlapping the first gate electrode 170 and having bottom concave and convex portions BCV and top concave and convex portions TCV provided in a length direction LD of the channel area CH, and a first source drain electrode 181 and a second source drain electrode 182 connected to both sides of the first active layer 150 while being spaced apart from the channel area CH of the first active layer 150.

Here, the bottom concave and convex portions BCV and the top concave and convex portions TCV of the first active layer 150 may vertically correspond to each other.

Since the first active layer 150 has concave and convex portions in the length direction LD of the channel area CH, even if the first active layer 150 is disposed so as to overlap the substrate 100 in the length direction LD with a short length, the channel is provided along the top and bottom concave and convex portions of the first active layer 150, thereby ensuring a sufficient channel length within the limited length of the substrate.

In particular, in recent display devices, high integration is required, and accordingly some transistors must be implemented as short channels. In transistors having such short channels, there is a problem that the channel becomes shorter due to the penetration of conductorization components or impurity components into the gate electrode during a conductorization process of the source drain area of the active layer or a doping process.

The transistor ATFT according to the first embodiment of the present disclosure has the effect that the bottom concave and convex portions BCV and the top concave and convex portions TCV are three-dimensionally provided along the channel length direction LD of the first active layer 150, thereby enabling the channel length to be extended within the same dimensions of the substrate 100. In addition, during the conductorization process or the doping process, the shape of the active layer 150 having the concave and convex portions may be designed such that concave portions have a vertical distance difference from flat portions, thereby mitigating the phenomenon where the conductorization components or the impurity components penetrate laterally into the gate electrode, thus preventing or reducing the phenomenon of the effective channel length becoming shorter.

Meanwhile, the first active layer 150 may include an oxide semiconductor material. In some cases, the first active layer 150 may include a crystalline silicon material.

When the first active layer 150 includes an oxide semiconductor material and has both the bottom concave and convex portions BCV and the top concave and convex portions TCV in the channel length direction, the phenomenon of effective channel length reduction due to channel length increase is resolved. Therefore, when the plurality of transistors is disposed on the substrate 100, a decrease in the reliability of the transistors provided on the substrate 100 may be resolved by reducing the threshold voltage spread range in the plurality of transistors.

As shown in FIG. 4, the first vertical distance H1 between the concave portions of the bottom concave and convex portions BCV of the first active layer 150 and the concave portions of the top concave and convex portions TCV may be the same as the second vertical distance H2 between the convex portions of the bottom concave and convex portions BCV and the convex portions of the top concave and convex portions TCV.

In addition, the first gate electrode 170 may have surface curves corresponding to the top concave and convex portions TCV of the first active layer 150. Here, the first gate electrode 170 is disposed along the thin first active layer 150 and a gate insulating layer 160 while having the shape of the top concave and convex portions TCV of the first active layer 150, thereby having concave and convex portions. The concave and convex portions of the upper surface of the first gate electrode 170 may have a smaller step height than the top concave and convex portions TCV of the first active layer 150.

An imprint layer 130 having first surface concave and convex portions CV corresponding in shape to the bottom concave and convex portions BCV is provided under the bottom concave and convex portions BCV of the first active layer 150.

A mold having concave and convex portions reversely corresponding to the first surface concave and convex portions CV may be provided, and the imprint layer 130 is stamped onto the mold such that the first surface concave and convex portions CV are provided in the imprint layer 130.

The imprint layer 130 may be controlled so as to have a thickness in the nanometer range, and the concave and convex portions may have a depth of 1 nm to 100 nm. Therefore, the first surface concave and convex portions CV of the imprint layer 130 may be provided only in a part of the total thickness of the imprint layer 130. Here, the total thickness of the imprint layer 130 may be 100 nm or more.

The imprint layer 130 includes an organic material, which is rearranged while having elasticity during a stamping process, and the first surface concave and convex portions CV are provided in the imprint layer 130 along the shape of the mold.

The first surface concave and convex portions CV may include a plurality of concave portions and a plurality of convex portions obtained by alternately forming concave portions having a certain depth from the flat surface of the imprint layer 130 and convex portions corresponding to the flat surface.

The bottom concave and convex portions BCV and top concave and convex portions TCV of the first active layer 150 located above may be applied along the first surface concave and convex portions CV of the imprint layer 130. The imprint layer 130 may be spaced apart from the first active layer 150 with a buffer layer 140 interposed therebetween.

The buffer layer 140 is configured to protect a formation surface of the first active layer 150, is made of a thin inorganic insulating material, and may be formed by directly applying the first surface concave and convex portions CV of the imprint layer 130.

The first active layer 150 abutting the buffer layer 140 abuts the upper surface of the buffer layer 140, to which the first surface concave and convex portions CV of the imprint layer 130 are applied, and has bottom concave and convex portions BCV following the first surface concave and convex portions CV of the imprint layer 130. Furthermore, since the first active layer 150 is provided with a small thickness, the first active layer 150 has top concave and convex portions TCV that are almost identical to the bottom concave and convex portions BCV.

The bottom concave and convex portions BCV of the first active layer 150 may have a shape in which convex portions abutting the upper surface of the buffer layer 140 and concave portions having a first depth from the upper surface of the buffer layer 140 are alternately provided a plurality of times.

The transistor ATFT according to the first embodiment includes first and second source drain electrodes 181 and 182 connected to both sides of the first active layer 150.

As such, the first active layer 150 has bottom concave and convex portions BCV and top concave and convex portions TCV, and when a channel is provided between the first source drain electrode 181 and the second source drain electrode 182, the bottom concave and convex portions BCV and the top concave and convex portions TCV are vertically and horizontally alternately provided along the length direction LD of the channel, thereby achieving an extended channel length effect.

Here, the first and second source drain electrodes 181 and 182 may be connected to the flat first active layer 150, or may abut the top concave and convex portions TCV having concave and convex portions in the length direction LD of the channel.

The first active layer 150 may have the top concave and convex portions TCV and the bottom concave and convex portions BCV over the entire surface thereof, or may have the top concave and convex portions TCV and the bottom concave and convex portions BCV only in the channel area CH overlapping the gate electrode 170.

When the first active layer 150 has the top concave and convex portions TCV and the bottom concave and convex portions BCV over the entire surface thereof, the first and second source drain electrodes 181 and 182 may be connected to the top concave and convex portions TCV of the first active layer 150 having the concave and convex portions.

In the transistor ATFT according to the first embodiment, the first active layer 150 having concave and convex portions in a current flowing direction, i.e., in the channel length direction LD, may be provided, whereby the channel length may be increased. That is, even if the transistor ATFT according to the first embodiment is placed within a short length area in the channel length direction LD, a channel length longer than the length of the plane on which the transistor is placed may be secured. This may solve the problem of reliability degradation of transistors caused by the conductorized area penetrating the channel area during the conductorization process, including short channels.

In the transistor ATFT according to the first embodiment, it is possible to set the density at which concave and convex portions are disposed in the channel length direction LD according to the required on-current Ion through the relationship where the on-current Ion is proportional to W (channel width)/L (channel length).

Meanwhile, a planarization layer 190 may be provided on the first and second source drain electrodes 181 and 182 for protection. The planarization layer 190 may be provided with a sufficient thickness to flatten the top of the step of the concave and convex structure of the lower electrode, thereby the light emitting device on the planarization layer 190 may not be affected by the concave and convex structure of the first active layer 150.

Hereinafter, a transistor having concave and convex portions in a channel width direction will be described.

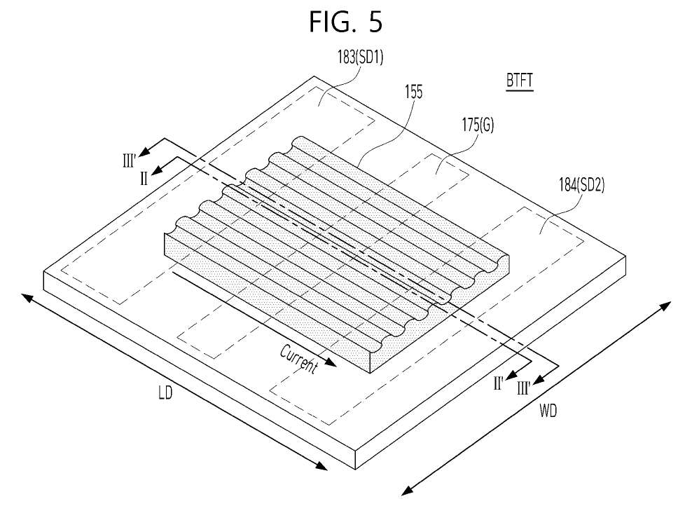

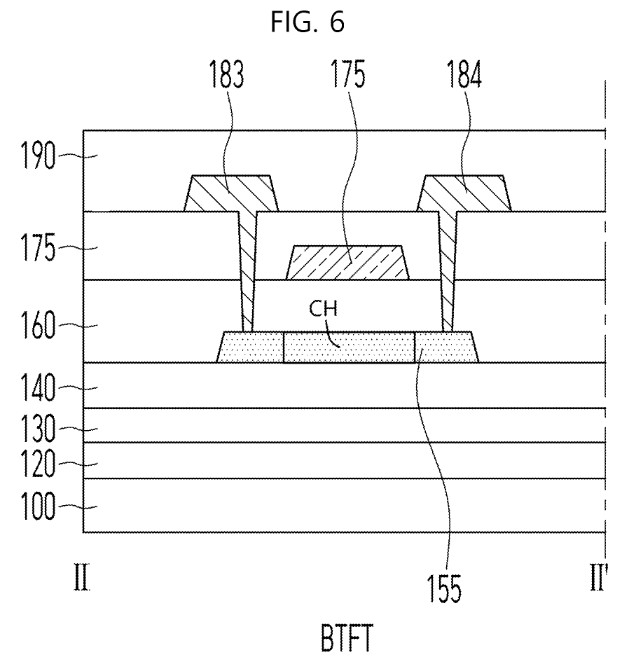

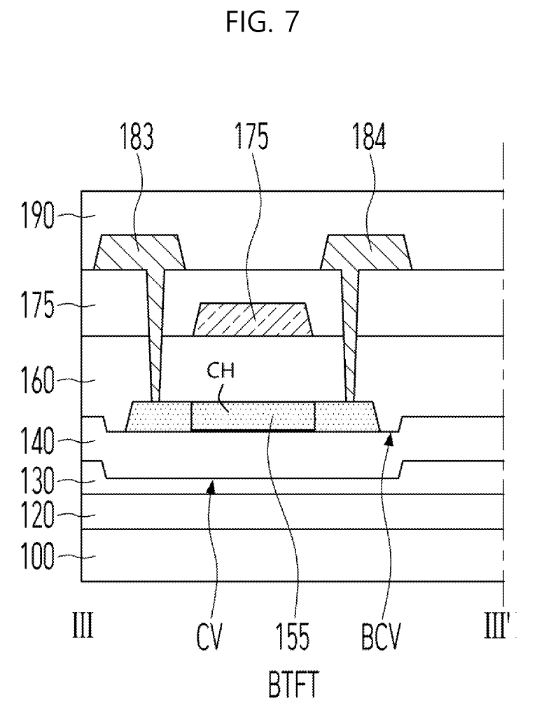

FIG. 5 is a plan view showing a transistor according to a second embodiment of the present disclosure, FIG. 6 is a sectional view taken along line II-II’ of FIGS. 5, and FIG. 7, is a sectional view taken along line III-III’ of FIG. 5.

As shown in FIGS. 5 to 7, the transistor BTFT according to the second embodiment of the present disclosure includes a second gate electrode 175 and a second active layer 155 overlapping the second gate electrode 175, having a channel area CH, and having bottom concave and convex portions and top concave and convex portions provided along a width direction WD of the channel area CH. In addition, the transistor BTFT according to the second embodiment includes third and fourth source drain electrodes 183 and 184 disposed parallel to the second gate electrode 175 along the concave and convex portions of the second active layer 155.

The transistor BTFT according to the second embodiment has the advantage that on-current Ion increases as the area through which current flows along the concave and convex portions of the second active layer 155 in the width direction WD of the channel increases.

The display device includes both the transistor BTFT in which the concave and convex portions are arranged on the first active layer 150 in the channel length direction LD, described with reference to FIGS. 3 and 4, and the transistor BTFT in which the concave and convex portions are arranged on the second active layer 155 in the channel width direction WD, described with reference to FIGS. 5 to 7. One of the transistor ATFT according to the first embodiment and the transistor BTFT according to the second embodiment may be used as a switching transistor for a subpixel, and the other may be used as a driving transistor. The transistor ATFT according to the first embodiment may increase the channel length within a limited area, and the transistor BTFT according to the second embodiment may increase the current of the transistor within a limited area to amplify the driving current of the subpixel.

In some cases, the transistor may be configured such that both the concave and convex portions in the channel length direction and the concave and convex portions in channel width direction are provided on the active layer, forming a planar lattice structure where the concave and convex portions are provided on the upper and lower surfaces of the active layer. The transistor in which the concave and convex portions are provided on the upper and lower surfaces of the active layer has the effect of increasing the channel length and amplifying the on-current.

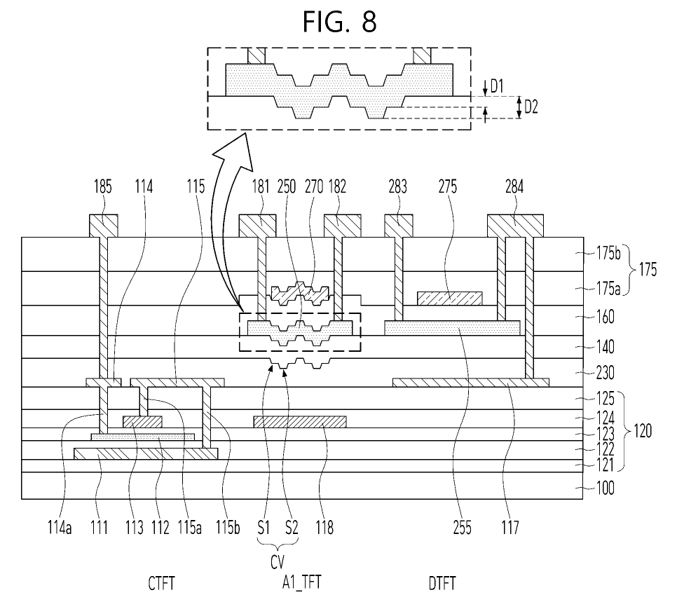

FIG. 8 is a sectional view showing various transistors according to an embodiment of the present disclosure.

Transistors, according to a third embodiment of the present invention, will be described with reference to FIG. 8.

In a first transistor A1_TFT according to a third embodiment, an active layer 250 has bottom concave and convex portions and top concave and convex portions in a multi-step structure having different depths D1 and D2. The multi-step structure of the active layer 250 may be provided according to surface concave and convex portions CV having different step heights S1 and S2 on an upper surface of an imprint layer 230.

In the first transistor according to the third embodiment, the multi-step concave and convex portions of the active layer 250 may be applied to a gate electrode 270 such that the gate electrode 270 has concave and convex portions.

Since the first transistor ATFT according to the third embodiment has multi-step concave and convex portions in the channel length direction, the channel length may be greater than that of the transistor according to the first embodiment.

The transistors provided in the display device may be provided in different forms for various purposes. There among, the switching transistor may have a short channel for high-speed operation, and the driving transistor may have a longer channel length than the switching transistor to enrich the gradation expression.

In this case, to overcome changes in the effective channel length that may occur during the conductorization or doping process for the switching transistor having the short channel, as shown in FIGS. 3 and 4, the first transistor having concave and convex portions in the channel length direction, as in the first embodiment, may be provided as the switching transistor, and the transistor having no concave and convex portions may be provided as the driving transistor.

Alternatively, to overcome changes in the effective channel length that may occur during the conductorization or doping process for the switching transistor may have the short channel, as shown in FIGS. 3 and 4, the first transistor having concave and convex portions in the channel length direction, as in the first embodiment, may be provided as the switching transistor, and the transistor in which the active layer has concave and convex portions in the channel width direction, as in the second embodiment described with reference to FIGS. 5 to 7 in order to improve the on-current, may be provided as the driving transistor.

First to third transistors A1_TFT, CTFT, and DTFT disposed in various stacks on the substrate 100 will be described in more detail with reference to FIG. 8.

The first transistor A1_TFT may include a first gate electrode 270 provided on the substrate 100 and a first active layer 250 overlapping the first gate electrode 270, having a first channel area, and having bottom concave and convex portions BCV and top concave and convex portions TCV in a length direction LD of the first channel area.

The first transistor A1_TFT includes source drain electrodes 181 and 182 connected to both sides of the first active layer 250.

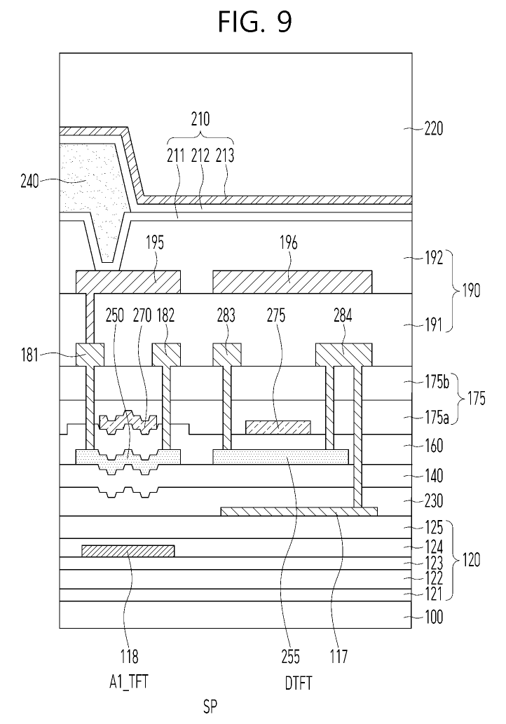

In the first transistor A1_TFT shown in FIGS. 8 and 9, the first active layer 250 has a plurality of concave portions having different depths at a bottom surface and a plurality convex portions corresponding to the bottom concave portions at a top surface. But the present disclosure is not limited thereto. That is, the first active layer 250 of the first transistor A1_TFT may be changed so as to have bottom concave and convex portions and top concave and convex portions in which concave portions and convex portions of the same depth are repeated, as shown in FIGS. 3 and 4. Since the concave and convex portions are provided in the channel length direction, the channel length may be increased within a limited substrate area even by this change.

In the example shown in FIG. 8, a first shielding pattern 118 is provided under the first active layer 250 of the first transistor A1_TFT.

The first shielding pattern 118 is configured to prevent light entering from the substrate 100 from affecting the first active layer 250.

Here, the first shielding pattern 118 is disposed lower than the imprint layer 230 and is not affected by a first surface step CV of the imprint layer 230. A plurality of insulating layers 124 and 125 having a protective function is provided between the first shielding pattern 118 and the imprint layer 230, and may prevent damage to lower patterns during the process of applying pressure to the imprint layer 230 using a mold.

A second transistor DTFT including a second gate electrode 275 and a second active layer 255 overlapping the second gate electrode 275, having a second channel area, and having a flat lower surface and upper surface provided along a length direction of the second channel area may be provided on the substrate 100.

The second transistor DTFT may include third and fourth source drain electrodes 283 and 284 connected to both sides of the second active layer 255.

Furthermore, the fourth source drain electrode 284 may further extend to the outside of the second active layer 255 and may be connected to the second shielding pattern 117 located under the second active layer 255.

Here, the first and second active layers 250 and 255 may be made of the same material and located on the same layer; however, the imprint layer 230 provided below selectively has a first surface step CV only in the area of the first transistor ATFT, and the second transistor DTFT is flat, allowing the first active layer 250 to have only bottom concave and convex portions and top concave and convex portions. The bottom concave and convex portions and the top concave and convex portions vertically correspond to each other.

Meanwhile, the active layers 250 and 255 of the first and second transistors A1_TFT and DTFT may each include an oxide semiconductor.

In addition to the first and second transistors ATFT and BTFT including the oxide semiconductors, a third transistor CTFT having an active layer 112 including crystalline silicon may be provided on the substrate 100.

The third transistor CTFT may include a third active layer 112, a third gate electrode 113 overlapping a channel area of the third active layer 112, and a source drain electrode 114 connected to one side of the third active layer 112. The source drain electrode 114 may be connected to the third active layer 112 via a contact hole 114a through the third to fifth insulating layers 123, 124, and 125.

In the third transistor CTFT, the third gate electrode 113 may be used as an upper gate, and a third light shielding pattern 111 disposed under the third active layer 112 to prevent incidence of light from the substrate 100 may be used as a lower gate.

Here, the third gate electrode 113 and the third shielding pattern 111 are connected to a connection pattern 115 via a first contact hole 115a and the second contact hole 115b, which branch vertically from the connection pattern 115 so as to be connected to the third gate electrode 113 and the third shielding pattern 111, respectively, such that the same gate voltage signal can be applied thereto.

Here, the first and second transistors ATFT and BTFT may be used as a switching transistor and a driving transistor of a subpixel, respectively. The third transistor CTFT may be used as a part of the switching transistor in the subpixel or as a transistor included in the gate-in-panel disposed in the non-active area NA of the substrate 100.

Each of first to fifth insulating layers 121, 122, 123, 124, and 125 sequentially provided on the substrate 100 is an inorganic insulating layer. Each of the first to fifth insulating layers 121, 122, 123, 124, and 125 may include at least one of silicon oxide (SiOx), silicon nitride (SiNx), and silicon oxynitride (SiOxNy), or a multilayer layer in which the aforementioned inorganic insulating layers are stacked.

The first insulating layer 121 is disposed on the substrate 100 to prevent impurities such as moisture or charge particles introduced through the substrate 100 from penetrating the structure on the substrate 100, and may function to planarize the surface. The first insulating layer 121 may serve as a buffer layer.

The insulating layers 120 disposed under the imprint layer 230 may be used as interlayer insulating layers for the third transistor CTFT including crystalline silicon.

The second insulating layer 122 may function as a buffer layer for planarizing a formation surface of the third active layer 112.

The third insulating layer 123 may function as a gate insulating layer of the third transistor CTFT.

The fourth insulating layer 124 and the fifth insulating layer 125 may function as interlayer insulating layers between the third gate electrode 133 and the source drain electrode 114.

The connection electrode 185 connected to the source drain electrode 114 of the third transistor CTFT may be used as wiring.

The insulating layers 175 (175a and 175b) between the first and second gate electrodes 270 and 275 and the source drain electrodes 181, 182, 283, and 284 may function as interlayer insulating layers. Each of the insulating layers 175 (175a and 175b) may be made of an inorganic insulating material such as silicon oxide or silicon nitride.

Meanwhile, the third transistor CTFT may be used in a circuit configuration provided in the non-active area NA, such as the gate-in-panel.

Hereinafter, the structure of a display device having the first transistor A1_TFT and the second transistor DTFT provided in a subpixel will be described by way of example.

FIG. 9 is a sectional view showing a display device according to an embodiment of the present disclosure.

The substrate 100 may be made of a plastic material having flexible properties. In an example, the substrate 100 may include first and second organic layers overlapping each other with an inorganic interlayer insulating layer therebetween. The first and second organic layers may include different organic layers that are homogeneous or heterogeneous, such as, polyethylene terephthalate (PET) and polyimide. In some cases, an adhesive layer such as a pressure sensitive adhesive (PSA) may be provided between the first and second organic layers.

In another example, the substrate 100 may include a thin glass material having flexibility.

The substrate 100 serves to support and protect components of the display device disposed thereon.

Each subpixel of the substrate 100 includes a first transistor A1_TFT having concave and convex portions provided along a length direction of a channel, described in the first embodiment or the third embodiment, and a second transistor DTFT having a flat surface provided along the length direction of the channel, unlike the first transistor A1_TFT. In the example of FIG. 9, the first transistor A1_TFT is connected to a light emitting device 210, but the present disclosure is not limited thereto. The second transistor BTFT may be connected to the light emitting device 210.

A plurality of insulating layers 120 (121, 122, 123, 124, and 125), an imprint layer 230, a buffer layer 140, a gate insulating layer 160, interlayer insulating layers 175 (175a and 175b), and planarization layers 190 (191 and 192) are sequentially disposed in the active area AA and the non-active area of the substrate 100.

The insulating layers 120 may include a first insulating layer 121, a second insulating layer 122, a third insulating layer 123, a fourth insulating layer 124, and a gate insulating layer 125.

In addition to the first transistor A1_TFT and the second transistor DTFT, a transistor having an active layer provided on another layer may be further provided on the substrate 100.

The first insulating layer 121 is disposed in the active area AA and the non-active area NA on the substrate 100. The first insulating layer 121 may be referred to as a buffer layer and may serve the same function as any buffer layer known in the art. The first insulating layer 121 may be disposed on the substrate 110 to protect structures located on substrate 110 from moisture penetrating through the substrate 110 and to planarize the surface of the substrate 110.

The first insulating layer 121 may extend to the edge of the substrate 110 to prevent moisture from penetrating from the edge of the substrate 110. The first insulating layer 121 may be a single inorganic layer or include a plurality of alternately stacked inorganic layers.

For example, the first insulating layer 121 may include one or more of silicon oxide (SiOx), silicon nitride (SiNx), silicon oxynitride (SiOxNy), or a multilayer layer in which the above-described inorganic layers are stacked.

The second insulating layer 122 and the third insulating layer 123 may be disposed on the first insulating layer 121. Each of the second insulating layer 122 and the third insulating layer 123 may function as a second buffer layer, for example. In this case, some of the transistors included in the subpixel may include a polysilicon semiconductor layer (not shown), and the second insulating layer 122 may be located under the polysilicon semiconductor layer. The second insulating layer 122 may include an inorganic layer, such as a silicon oxide (SiOx) layer, a silicon nitride (SiNx) layer, or a multilayer layer thereof. In some cases, the second insulating layer 122 may be used as a gate insulating layer if a transistor including a polysilicon semiconductor layer.

A first shielding pattern 118 made of a conductive metal material may be provided on the third insulating layer 123. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

The first shielding pattern 118 may form one electrode of the storage capacitor included in the subpixel.

The fourth insulating layer 124 and the fifth insulating layer 125 may be provided on the first shielding pattern 118.

A second shielding pattern 117 made of a conductive metal material is disposed on the fifth insulating layer 125. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

The first and second shielding patterns 118 and 117 may be located on the same layer as the storage capacitor or the first electrode and the second electrode of the capacitor. Each of the first and second shielding patterns 118 and 117 may have a single layer or may have a structure in which a plurality of different metal materials is stacked.

An imprint layer 230 made of an organic material is provided on the fifth insulating layer 125 provided with the second shielding pattern 117. After applying an organic material with a thickness in the nanometer range, an upper surface of the first transistor ATFT may be stamped using a mold, whereby an imprint layer 230 having first surface concave and convex portions CV (see FIG. 8) may be provided.

Top concave and convex portions are disposed on the imprint layer 230 along the first surface concave and convex portions of the imprint layer 230, and a flat buffer layer 140 is provided in the remaining area.

The buffer layer 140 may include an inorganic material. The inorganic material may include, for example, a silicon oxide (SiOx) layer or a multilayer layer including stacked inorganic layers.

The first active layer 250 and the second active layer 255 are provided on the buffer layer 140.

Here, the first active layer 250 provided in the first transistor A1_TFT region has bottom concave and convex portions and top concave and convex portions corresponding to the first surface concave and convex portions CV of the imprint layer 230. On the other hand, the second active layer 255 provided in the second transistor BTFT is flat.

Each of the first and second active layers 250 and 255 include, for example, an oxide semiconductor material. The oxide semiconductor material may include a combination of at least one of zinc (Zn), indium (In), gallium (Ga), tin (Sn), and titanium (Ti) and an oxide. In some cases, a highly conductive metal such as iron (Fe) may be further included in the oxide semiconductor material to increase mobility.

In the embodiments of the present disclosure, the first active layer 250 is provided with concave and convex portions in the channel length direction such that the channel length increases along the top and bottom concave and convex portions of the first active layer 250 within a limited area of the substrate 100, thereby solving the problem of reduced effective channel length in a short-channel transistor.

In some cases, the first active layer 250 and the second active layer 255 may have different mobilities so as to correspond to the response speed of each transistor.

More specifically, examples of the oxide semiconductor material constituting each of the first and second active layers 250 and 255 may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), and iron-indium-zinc oxide (FIZO). For different mobilities, the metal components contained in the oxide of each of the first and second active layers 250 and 255 may be different or the ratio of the plurality of metal components may be different.

A gate insulating layer 160 is disposed so as to cover the first active layer 250 and the second active layer 255.

First and second gate electrodes 270 and 275 are disposed on the gate insulating layer 160. Each of the first and second gate electrodes 270 and 275 may include at least one of an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). Each of the first and second gate electrodes 270 and 275 may have a single layer or multiple layers.

After forming the first and second gate electrodes 270 and 275, an active layer ACT, a first active layer 250, and a second active layer 255 may be doped using the same as a mask to form a conductorized area. Each of the first active layer 250 and the second active layer 255 may have a channel in an area overlapping the gate electrodes 270 and 275 and a doped conductorized area in an area outside the first and second gate electrodes 270 and 275.

A first interlayer insulating layer 175a and a second interlayer insulating layer 175b are disposed on the gate insulating layer 160 on which the first and second gate electrodes 270 and 275 are disposed.

Each of the first interlayer insulating layer 175a and the second interlayer insulating layer 175b may be made of an inorganic insulating material and may have a single layer in some cases.

Each of the first interlayer insulating layer 175a and the second interlayer insulating layer 175b may include, for example, a silicon oxide (SiOx) layer, a silicon nitride (SiNx) layer, or a multilayer layer in which the inorganic layers are stacked.

The first and second interlayer insulating layers 175a and 175b and the gate insulating layer 160 are selectively removed to form a contact hole exposing both sides of the first and second active layers 250 and 255. In the same process, the buffer layer 140 and the imprint layer 230 may be partially removed such that a part of the second shielding pattern 117 is exposed.

With the contact hole exposed, high-temperature thermal treatment is performed for one hour or more to release mobile hydrogen ions from the first and second active layers 250 and 255 and the insulating layers 175, 160, 140, and the imprinting layer 230.

After releasing the hydrogen ions, a metal material is provided on the interlayer insulating layer 175 and is selectively removed to form first to fourth source drain electrodes 181, 182, 283, and 284 connected to the first and second active layers 250 and 255 through the contact hole. Here, the fourth source drain electrode 284 may be connected to the second shielding pattern 117.

Each of the first to fourth source drain electrodes 181, 182, 283, and 284 may include at least one of an aluminum-based metal, such as aluminum (Al) or an aluminum alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

A first planarization layer 191 configured to protect the first and second transistors ATFT and BTFT may be provided on the first to fourth source drain electrodes 181, 182, 283, and 284.

A connection electrode 195 connecting the first source drain electrode 181 and a first electrode 211 may be provided on the first planarization layer 191, and a cover electrode 196 covering the second transistor BTFT to prevent interference with an upper light emitting device may further be provided on the same layer.

A second planarization layer 192 covering the connection electrode 195 and the cover electrode 196 is further provided, and the connection electrode 195 may be exposed through a contact hole in the second planarization layer 192. The connection electrode 195 and the first electrode 211 are connected through the contact hole in the second planarization layer 192.

The first and second planarization layers 191 and 192 planarize a formation surface where a first electrode 211 is provided, and are collectively referred to as a planarization layer 190. Each of the first and second planarization layers 191 and 192 may include an organic material. The organic material may include at least one of an acrylic resin, a phenolic resin, a polyimide resin, an unsaturated polyester resin, a polyamide resin, or a polyester resin, benzocyclobutene, a polyphenylene resin, and a polyphenylene sulfide resin.

A first electrode 211 is further provided on the planarization layer 190, and may be electrically connected to the first source drain electrode 181 through the contact hole in the planarization layers 191 and 192. The first electrode 211, a second electrode 213 opposite thereto, and an intermediate layer 212 between the first electrode 211 and the second electrode 213 constitute a light emitting device ED.

One of the first electrode 211 and the second electrode 213 may include a reflective electrode, and the other may include a transparent electrode or a transflective electrode.

When the first electrode 211 includes a reflective electrode, the 211 may function to shield light incident on the transistor TFT thereunder. The first electrode 211 may include, for example, a stacked structure of a first transparent electrode, a reflective electrode, and a second transparent electrode. The second transparent electrode, which is the uppermost electrode of the first electrode 211, may be a dielectric and may lower the barrier through which holes are injected at the interface with the intermediate layer 212. Here, the first and second transparent electrodes may be transparent oxide electrodes such as ITO or IZO. The reflective electrode may include silver, a silver alloy such as APC (Ag-Pd-Cu), aluminum, or an aluminum alloy.

For example, the first electrode 211 may be provided as a multilayer structure, such as a stack structure of aluminum (Al) and titanium (Ti) (Ti/Al/Ti), a stack structure of aluminum (Al) and ITO (ITO/Al/ITO), an APC (Ag/Pd/Cu) alloy, and a stack structure of an APC alloy and ITO (ITO/APC/ITO), or a stack structure of silver (Ag) and a molybdenum/titanium alloy (Ag/MoTI), or may include a monolayer structure made of any one selected from along silver (Ag), aluminum (Al), molybdenum (Mo), gold (Au), magnesium (Mg), calcium (Ca), and barium (Ba), or an alloy of two or more thereof.

A pixel defining layer 240 is disposed so as to surround the edge of the first electrode 211, and a light emitting area may be defined in an open area of the pixel defining layer 240. The pixel defining layer 240 may extend into the non-active area NA, and may be at least partially overlap the gate-in-panel GIP.

The pixel defining layer 240 may include an inorganic material or an organic material. The pixel defining layer 240 may include an opaque material (e.g., black) to prevent optical interference between neighboring subpixels SP. In this case, the pixel defining layer 240 may include a shielding material including at least one of color pigment, organic black, and carbon.

The intermediate layer 212 may include a hole injection layer, a hole transport layer, a light emitting layer, an electron transport layer, and an electron injection layer. The intermediate layer 212 may be provided in a tandem structure including a plurality of stacks, each including a hole transport layer, a light emitting layer, and an electron transport layer, and a charge generation layer provided between the stacks. The charge generation layer may include, for example, an n-type charge generation layer and a p-type charge generation layer.

The light emitting layer included in the intermediate layer 212 may be configured differently for each subpixel. The light emitting layer EL may include a red light emitting layer that emits red light, a green light emitting layer that emits green light, and a blue light emitting layer that emits blue light. The red light emitting layer, the green light emitting layer, and the blue light emitting layer may be disposed per subpixel SP on the first electrode 211.

For example, a red light emitting layer may be patterned and disposed in a red subpixel, a green light emitting layer may be patterned and disposed in a green subpixel, and a blue light emitting layer may be patterned and disposed in a blue subpixel. However, the present disclosure is not necessarily limited thereto, and at least two of the red light emitting layer, the green light emitting layer, and the blue light emitting layer may be stacked and disposed in one subpixel SP.

In some cases, the light emitting layer may be a white light emitting layer that emits white light. In this case, the light emitting layer EL may be in the form of a common layer in which one or more layers are disposed in common in the subpixels SP rather than in the form of a pattern in the subpixels SP.

As described above, the intermediate layer 212 may be disposed in a tandem structure of two or more stacks. In this case, each of the light emitting devices ED may include a charge generation layer disposed between the stacks. The charge generation layer may be a common layer disposed on the entire surface of the active area AA.

The second electrode 213 may be provided by a transparent electrode, such as ITO or IZO, or a thin transflective electrode, such as silver, a silver alloy, magnesium, a magnesium alloy, ytterbium (Yb), or an ytterbium alloy. In other embodiments, the second electrode 213 may be partially removed from a transmission area or formed with a thin thickness to increase the transmittance in the transmission area. The second electrode 213 may be a common layer disposed in common in the subpixels SP and applying the same voltage. To this end, the second electrode 213 may extend from the active area AA to a part of the non-active area NA.

The second electrode 213 may be a light transmissive electrode. The second electrode 213 may include a transparent conductive material (TCO), such as ITO or IZO, or a semi-transmissive conductive material such as magnesium (Mg), silver (Ag), or an alloy of magnesium (Mg) and silver (Ag) that is capable of transmitting light. If the second electrode 213 includes a semi-transmissive conductive material, light emission efficiency may be increased by the microcavity effect.

The top emission type light emitting device 210 was previously described by way of example. However, the light emitting device ED of the present disclosure is not limited thereto, and may be a bottom emission type light emitting device in which light emitted from the intermediate layer 212 is emitted toward the substrate 100. In this case, the first electrode 211 may be made of a transparent electrode material or a semi-transparent electrode material, and the second electrode 213 may be made of a reflective electrode material.

An encapsulation layer 220 is disposed on the light emitting device 210. The encapsulation layer 220 may cover the active area AA and the non-active area NA to prevent oxygen or moisture from infiltrating the light emitting device ED. Other layers, such as a capping layer, may be interposed between the encapsulation layer 220 and the second electrode 213 as desired.

The encapsulation layer 220 may include a plurality of layers. The encapsulation layer 220 may have a structure in which an inorganic layer including an inorganic insulating material and an organic layer including an organic insulating material are alternately stacked. For example, the inorganic insulating material may include one or more materials such as silicon oxide, silicon nitride, and/or silicon oxynitride.

The organic insulating material may include one or more materials selected from the group consisting of polyethylene terephthalate, polyethylene naphthalate, polycarbonate, polyimide, polyethylene sulfonate, polyoxymethylene, polyarylate, and hexamethyldisiloxane.

A capping layer (not shown) may be further provided on the second electrode 213 to protect the second electrode 213 of the light emitting device 210 and to increase upward light emission efficiency.

A transistor according to one embodiment of the present disclosure may comprise a gate electrode, an active layer comprising a channel area overlapping the gate electrode, and having bottom concave and convex portions and top concave and convex portions provided along a length direction of the channel area; and a first source drain electrode and a second source drain electrode connected to both sides of the active layer, the first source drain electrode and the second source drain electrode being spaced apart from the channel area of the active layer.

In a transistor according to one embodiment of the present disclosure, the bottom concave and convex portions and the top concave and convex portions of the active layer may vertically correspond to each other.

In a transistor according to one embodiment of the present disclosure, a first vertical distance between the bottom concave portions and the top concave portions, and a second vertical distance between the bottom convex portions and the top convex portions may be identical.

In a transistor according to one embodiment of the present disclosure, the gate electrode may have surface curves corresponding to the top concave and convex portions of the active layer.

A transistor according to one embodiment of the present disclosure may further comprise an imprint layer having first surface concave and convex portions corresponding in shape to the bottom concave and convex portions under the bottom concave and convex portions of the active layer. The imprint layer may be spaced apart from the active layer with a buffer layer interposed therebetween.

In a transistor according to one embodiment of the present disclosure, the bottom concave and convex portions of the active layer may be provided in the buffer layer with a plurality of concave part each having different depths.

In a transistor according to one embodiment of the present disclosure, the imprint layer may comprise an organic material.

In a transistor according to one embodiment of the present disclosure, the bottom concave and convex portions of the active layer may have a shape in which convex portions abutting an upper surface of the buffer layer and concave portions having a first depth from the upper surface of the buffer layer are alternately provided a plurality of times.

In a transistor according to one embodiment of the present disclosure, the active layer may comprise an oxide semiconductor.

A transistor according to one embodiment of the present disclosure further may comprise a shielding pattern under the imprint layer, the shielding pattern corresponding to the active layer.

A display device according to one embodiment of the present disclosure may comprise a first transistor comprising a first gate electrode and a first active layer overlapping the first gate electrode, having a first channel area, and having bottom concave and convex portions and top concave and convex portions provide along a length direction of the first channel area and a second transistor comprising a second gate electrode and a second active layer overlapping the second gate electrode, having a second channel area, and having bottom concave and convex portions and top concave and convex portions provided along in a width direction of the second channel area.

In a display device according to one embodiment of the present disclosure, each of the first active layer and the second active layer may comprise an oxide semiconductor.

In a display device according to one embodiment of the present disclosure, the first transistor or the second transistor may be electrically connected to a light emitting device via a source drain electrode.

A display device according to one embodiment of the present disclosure may further comprise a third transistor comprising a third active layer located on a layer different from the first active layer.

In a display device according to one embodiment of the present disclosure, each of the first and second active layers may comprise an oxide semiconductor, and the third active layer may comprise a polycrystalline silicon.

A display device according to one embodiment of the present disclosure may comprise a first transistor comprising a first gate electrode and a first active layer overlapping the first gate electrode, having a first channel area, and having bottom concave and convex portions and top concave and convex portions along a length direction of the first channel area and a second transistor comprising a second gate electrode and a second active layer overlapping the second gate electrode, having a second channel area, and having a flat lower surface and a flat upper surface along a length direction of the second channel area.

In a display device according to one embodiment of the present disclosure, each of the first active layer and the second active layer may comprise an oxide semiconductor.

In a display device according to one embodiment of the present disclosure, the first transistor or the second transistor may be electrically connected to a light emitting device via a source drain electrode.

A display device according to one embodiment of the present disclosure may further comprise a third transistor comprising a third active layer located on a layer different from the first active layer.

As is apparent from the above description, a transistor according to the present disclosure and a display device including the same have the following effects.

In the transistor according to the embodiment of the present disclosure, a concave and convex structure may be applied to an upper surface and a lower surface of an active layer, whereby it is possible to secure the channel length within a limited area of a substrate. Particularly, in a switching transistor used as a short channel, a sufficient channel length may be secured even when the area is limited, whereby it is possible to implement a stable transistor with a small dispersion range.

The transistor according to the embodiment of the present disclosure may include a first transistor having concave and convex portions provided along a length direction of the channel of the active layer and a second transistor having concave and convex portions provided along a width direction of the channel, whereby it is possible to implement a transistor for different purposes such as securing channel length and securing on-current.

In the transistor according to the embodiment of the present disclosure, concave and convex portions may be provided in different directions depending on the characteristics of a transistor provided in a subpixel, whereby it is possible to define the channel characteristics for various purposes such as high-speed operation or gradation expression. A hydrogen release path of the active layer may be disposed outside a central area of the channel and outside an edge area of the channel so as to have different densities such that the channel length change can be adjusted by area, whereby it is possible to prevent variation in channel length change.

In the embodiment of the present disclosure, the effective channel length change of a transistor including an oxide semiconductor may be controlled, whereby it is possible to improve reliability of the transistor.

In the display device according to the embodiment of the present disclosure, the defect rate of the display device may be reduced such that the amounts of materials used in the process of manufacturing the display device, such as gas and an etching solution, can be reduced, whereby it is possible to reduce greenhouse gases generated by the manufacturing process.

In the display device according to the embodiment of the present disclosure, the effective channel length change in the transistor may be controlled, the threshold voltage sensitivity may be reduced, enabling the application of high-power transistors in small sizes and reducing power consumption, thereby providing the advantage of low-power operation. In the display device, therefore, environmentally and socially continuous applicability is possible, whereby ESG (environmental/social/governance) goals may be achieved.

What is claimed is:

1. A transistor comprising:
a gate electrode;
an active layer comprising a channel area overlapping the gate electrode, and having bottom concave and convex portions and top concave and convex portions provided along a length direction of the channel area; and
a first source drain electrode and a second source drain electrode connected to both sides of the active layer, the first source drain electrode and the second source drain electrode being spaced apart from the channel area of the active layer.

2. The transistor according to claim 1, wherein the bottom concave and convex portions and the top concave and convex portions of the active layer vertically correspond to each other.

3. The transistor according to claim 1, wherein a first vertical distance between the bottom concave portions and the top concave portions, and a second vertical distance between the bottom convex portions and the top convex portions are identical.

4. The transistor according to claim 1, wherein the gate electrode has surface curves corresponding to the top concave and convex portions of the active layer.

5. The transistor according to claim 1, further comprising an imprint layer having first surface concave and convex portions corresponding in shape to the bottom concave and convex portions under the bottom concave and convex portions of the active layer,
wherein the imprint layer is spaced apart from the active layer with a buffer layer interposed therebetween.

6. The transistor according to claim 5, wherein the bottom concave and convex portions of the active layer are provided in the buffer layer with a plurality of concave part each having different depths.

7. The transistor according to claim 5, wherein the imprint layer comprises an organic material.

8. The transistor according to claim 5, wherein the bottom concave and convex portions of the active layer have a shape in which convex portions abutting an upper surface of the buffer layer and concave portions having a first depth from the upper surface of the buffer layer are alternately provided a plurality of times.

9. The transistor according to claim 1, wherein the active layer comprises an oxide semiconductor.

10. The transistor according to claim 5, further comprising a shielding pattern under the imprint layer, the shielding pattern corresponding to the active layer.

11. A display device comprising:
a first transistor comprising a first gate electrode and a first active layer overlapping the first gate electrode, having a first channel area, and having bottom concave and convex portions and top concave and convex portions provided along a length direction of the first channel area; and
a second transistor comprising a second gate electrode and a second active layer overlapping the second gate electrode, having a second channel area, and having bottom concave and convex portions and top concave and convex portions provided along a width direction of the second channel area.

12. The display device according to claim 11, wherein each of the first active layer and the second active layer comprises an oxide semiconductor.

13. The display device according to claim 11, wherein the first transistor or the second transistor is electrically connected to a light emitting device via a source drain electrode.

14. The display device according to claim 11, further comprising a third transistor comprising a third active layer located on a layer different from the first active layer.

15. The display device according to claim 14, wherein:
each of the first and second active layers comprises an oxide semiconductor, and
the third active layer comprises a polycrystalline silicon.

16. A display device comprising:
a first transistor comprising a first gate electrode and a first active layer overlapping the first gate electrode, having a first channel area, and having bottom concave and convex portions and top concave and convex portions along a length direction of the first channel area; and
a second transistor comprising a second gate electrode and a second active layer overlapping the second gate electrode, having a second channel area, and having a flat lower surface and a flat upper surface along a length direction of the second channel area.

17. The display device according to claim 16, wherein each of the first active layer and the second active layer comprises an oxide semiconductor.

18. The display device according to claim 16, wherein the first transistor or the second transistor is electrically connected to a light emitting device via a source drain electrode.

19. The display device according to claim 16, further comprising a third transistor comprising a third active layer located on a layer different from the first active layer.
